(19) United States
(12) Patent Application Publication
(10) Pub. No.: US 2009/0219675 A1
(43) Pub. Date: Sep. 3, 2009

(54) ELECTRONIC DEVICE WITH INTERCHANGEABLE FRAME

(75) Inventors: LI-ZHANG HUANG, Tu-Cheng (TW); WEN-HSIANG LU, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/344,454

(22) Filed: Dec. 26, 2008

(30) Foreign Application Priority Data
Feb. 29, 2008 (CN) 200810065468.3

(51) Int. Cl. H05K 7/00; A47G 1/16

(52) U.S. Cl. 361/679.01; 248/466

(57) ABSTRACT

An electronic device includes a main body and a frame. The frame includes a back part and a front part. The back part defines a front surface, a back surface, a first inner surface and a second inner surface, and includes shoulders extended face to face from boundaries of the first inner surface, the second inner surface and the back surface. The first inner surface and the second inner surface face to each other. The front part is attached to the front surface of the back part. The frame further includes resilient means disposed on the first surface. The main body is received in the frame, two opposite ends of the main body respectively contact with the resilient means and the second inner surface. The front part and the shoulders keep the main body in the frame. The electronic device can change the frame, thus to change appearance easily.

### BACKGROUND

1. Technical Field

The disclosure relates to an electronic device having an interchangeable frame.

2. General Background

Electronic devices, such as digital photo frames, can be operated to change content displayed easily. Yet, the appearance of the electronic device is always the same, and therefore is not appealing to users who may wish a change.

FIG. 4 shows an electronic device with an interchangeable frame. The electronic device includes a main body 2 and a frame 3. The frame 3 receives the main body 2. Screws 4 connect the main body 2 and the frame 3. Applying different frames 3 can vary the appearance of the electronic device, but removing and replacing screws 4 is tedious and time consuming. Furthermore, the main body 2 must define screw holes, thus, the frame 3 is not suitable for an electronic device without properly configured screw holes.

Thus, what is needed is an electronic device with conveniently changeable appearance, and a frame which can be applied to various electronic devices.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic, exploded view of an electronic device according to an exemplary embodiment.

FIG. 2 is a schematic, isometric view of the electronic device of FIG. 1.

FIG. 3 is a section view of FIG. 2, taken along the line II-II in FIG. 2.

FIG. 4 is a schematic, exploded view of a conventional electronic device of the related art.

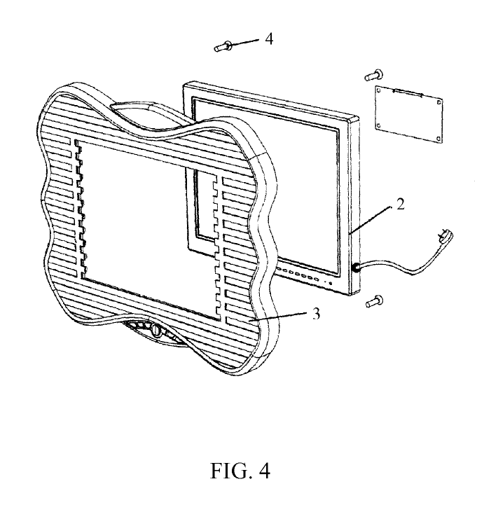

### DETAILED DESCRIPTION OF THE EMBODIMENTS

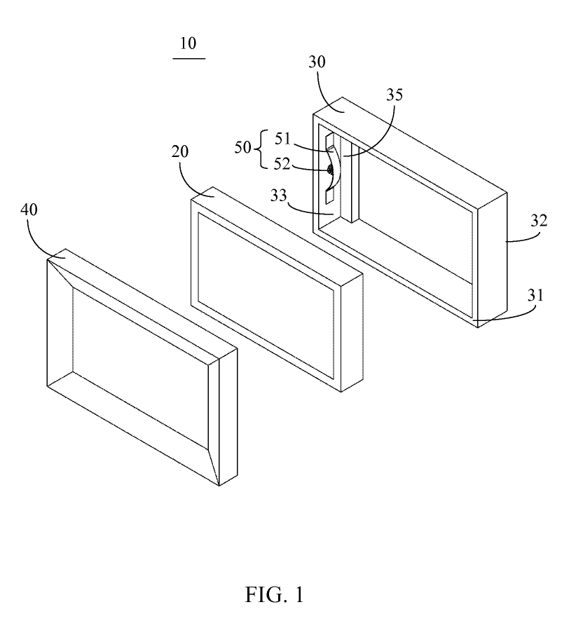

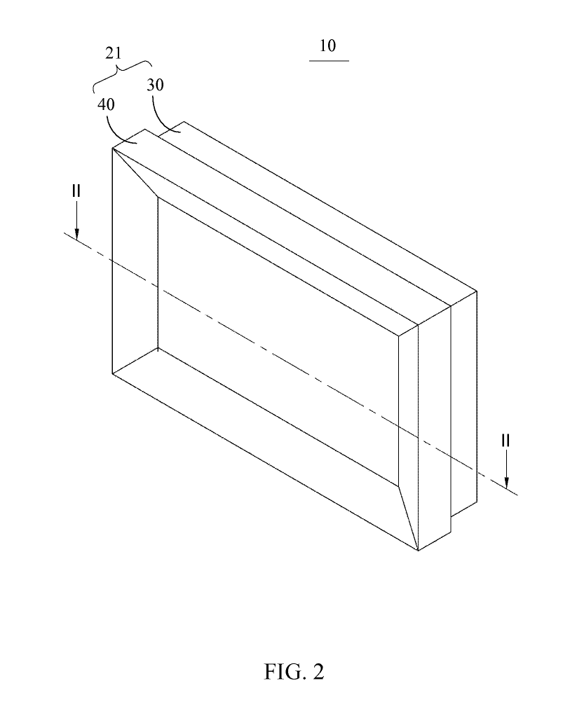

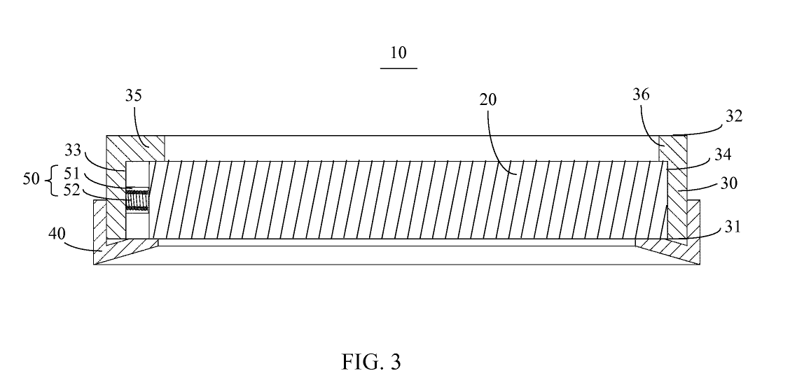

Referring to FIGS. 1 to 3, an electronic device 10 is disclosed. The electronic device 10 includes a main body 20 and a frame 21. The frame 21 includes a back part 30 and a front part 40.

The back part 30 defines a front surface 31, a back surface 32, a first inner surface 33, and a second inner surface 34. The first and second inner surfaces 33, 34 face to each other. Shoulders 35, 36 extend face to face from the boundaries of the first inner surface 33, the second inner surface 34, respectively, and the back surface 32. A width between the first and second inner surfaces 33, 34 is greater than a width of the main body 20. A width between the shoulders 35, 36 is less than the width of the main body 20. A resilient means 50 is disposed on the first inner surface 33. The resilient means 50 includes an elastic piece 51 and a spring 52. The front part 40 may be attached to the front surface 31 of the back part 30 by screws, glues, or other connection means. Appearance of the front part 40 can be varied if desired, such as designing in different shapes, textures and colors.

When the electronic device 10 is assembled, first, an end of the main body 20 is pushed to enter into the frame 21 through an opening between the shoulders 35, 36, and to compress the resilient means 50. Then an opposite end of the main body 20 enters into the frame 21 through the opening between the shoulders 35, 36. Then, a pushing force applied to the main body 20 is removed and the resilient means 50 restores to push the opposite end of the main body 20 to contact with the second inner surface 34. In this way, the main body 20 and the frame 21 are assembled together. The shoulders 35, 36 and the front part 40 keep the main body 20 in the frame 21.

When the electronic device 10 is disassembled, first, the main body 20 is pushed to compress the resilient means 50, an end of the main body 20 far from the resilient means 50 moves to leave from the second inner surface 34 and the shoulder 36 correspondingly. Then the end of the main body 20 goes out of the frame 21 through the opening between the shoulders 35, 36. In this way, the electronic device 10 is disassembled.

The main body 20 and the frame 21 can be assembled and disassembled easily, to exchange the frame 21 with another frame having a different configuration, thus appearance of the electronic device 10 can be easily changed and the frame 21 can be applied to other electronic device having similar shape as the electronic device 10.

Moreover, it is to be understood that the invention may be embodied in other forms without departing from the spirit thereof. Thus, the present examples and embodiments are to be considered in all respects as illustrative and not restrictive, and the invention is not to be limited to the details given herein.

What is claimed is:

1. An electronic device comprising:
a frame comprising:
a back part defining a front surface, a back surface, a first inner surface and a second inner surface, and comprising shoulders extended face to face from boundaries of the first inner surface, the second inner surface and the back surface, wherein the first inner surface and the second inner surface face to each other;
a front part attached to the front surface of the back part; and
resilient means disposed on the first inner surface; and
a main body received in the frame, wherein two opposite ends of the main body respectively contact with the resilient means and the second inner surface, the front part and the shoulders keep the main body in the frame.

2. The electronic device of claim 1, wherein the resilient means comprises an elastic piece.

3. The electronic device of claim 1, wherein the resilient means comprises a spring.

4. A frame comprising:
a back part defining a front surface, a back surface, a first inner surface and a second inner surface, and comprising shoulders extended face to face from boundaries of the first inner surface, the second inner surface and the back surface, wherein the first inner surface and the second inner surface face to each other;
a front part attached to the front surface of the back part; and
resilient means disposed on the first surface.

5. The frame of claim 4, wherein the resilient means comprises an elastic piece.

6. The frame of claim 4, wherein the resilient means comprises a spring.
